(19) United States
(12) Patent Application Publication
(10) Pub. No.: US 2025/0094665 A1
(43) Pub. Date: Mar. 20, 2025

(54) INFORMATION PROCESSING DEVICE, INFORMATION PROCESSING METHOD, AND COMPUTER PROGRAM PRODUCT

(71) Applicant: KABUSHIKI KAISHA TOSHIBA, Tokyo (JP)

(72) Inventors: Kei MATSUOKA, Kawasaki Kanagawa (JP); Yuki MIYACHI, Kawasaki Kanagawa (JP); Akihiko ENAMITO, Kawasaki Kanagawa (JP)

(73) Assignee: KABUSHIKI KAISHA TOSHIBA, Tokyo (JP)

(21) Appl. No.: 18/732,981

(22) Filed: Jun. 4, 2024

(30) Foreign Application Priority Data
Sep. 19, 2023 (JP) 2023-151421

(51) Int. Cl. G06F 30/20

(52) U.S. Cl. CPC G06F 30/20

(57) ABSTRACT

An information processing device according to an embodiment includes a processor connected to a memory. The processor serves to identify, as resonant frequency of components of a structure, frequency of first-type peaks included in a first-type transfer function waveform representing relationship between amplitude and frequency of output vibration. The output vibration occurs in the components of the structure when the structure is subjected to sweep excitation. The processor serves to calculate a vibration propagation path along which input vibration having the resonant frequency propagates when applied to the structure. The vibration propagation path is calculated based on frequency and half width of second-type peaks included in a second-type transfer function waveform representing relationship between amplitude and frequency of output vibration. The output vibration occurs in at least part of the components of the structure when the input vibration is applied to the structure for a predetermined vibration excitation duration.

### CROSS-REFERENCE TO RELATED APPLICATIONS

This application is based upon and claims the benefit of priority from Japanese Patent Application No. 2023-151421, filed on Sep. 19, 2023; the entire contents of which are incorporated herein by reference.

### FIELD

Embodiments described herein relate generally to an information processing device, an information processing method, and a computer program product.

### BACKGROUND

There is a disclosed technology for identifying a vibration source in a structure that is made of a plurality of components.

In one example of such a technology, vibrations are input to the structure in order to forcibly cause vibration excitation of the structure. The resonant frequency is identified by analyzing vibrations occurring in the structure due to the vibration excitation. Then, the component that is tuned to the resonant frequency is identified as the vibration source.

In some cases, when vibrations occurring in a particular component propagate to the other components, a vibration propagation path is formed inside the structure. In the conventional technology, it is difficult to identify such a vibration propagation path.

### BRIEF DESCRIPTION OF THE DRAWINGS

FIG. 1 is a schematic diagram illustrating an information processing system;

FIG. 2 is an explanatory diagram illustrating sweep excitation;

FIG. 3 is a schematic diagram illustrating a first-type transfer function waveform;

FIGS. 4A and 4B are diagrams illustrating vibration excitation attributed to the input vibrations having a resonant frequency;

FIG. 5 is a schematic diagram illustrating a second-type transfer function waveform;

FIG. 6 is an explanatory diagram illustrating a vibration propagation path R;

FIG. 7 is a flowchart for explaining a procedure of information processing; and

FIG. 8 is a hardware configuration diagram.

### DETAILED DESCRIPTION

An information processing device according to one embodiment includes a hardware processor connected to a memory. The hardware processor is configured to identify, as resonant frequency of components of a structure, frequency of first-type peaks included in a first-type transfer function waveform representing relationship between amplitude and frequency of output vibration. The output vibration occurs in the components of the structure when the structure is subjected to sweep excitation. The hardware processor is configured to calculate a vibration propagation path along which input vibration having the resonant frequency propagates when applied to the structure. The vibration propagation path is calculated based on frequency and half width of second-type peaks included in a second-type transfer function waveform representing relationship between amplitude and frequency of output vibration. The output vibration occurs in at least part of the components of the structure when the input vibration is applied to the structure for a predetermined vibration excitation duration.

An exemplary embodiment of an information processing device, an information processing method, and a computer program product will be described below in detail with reference to the accompanying drawings.

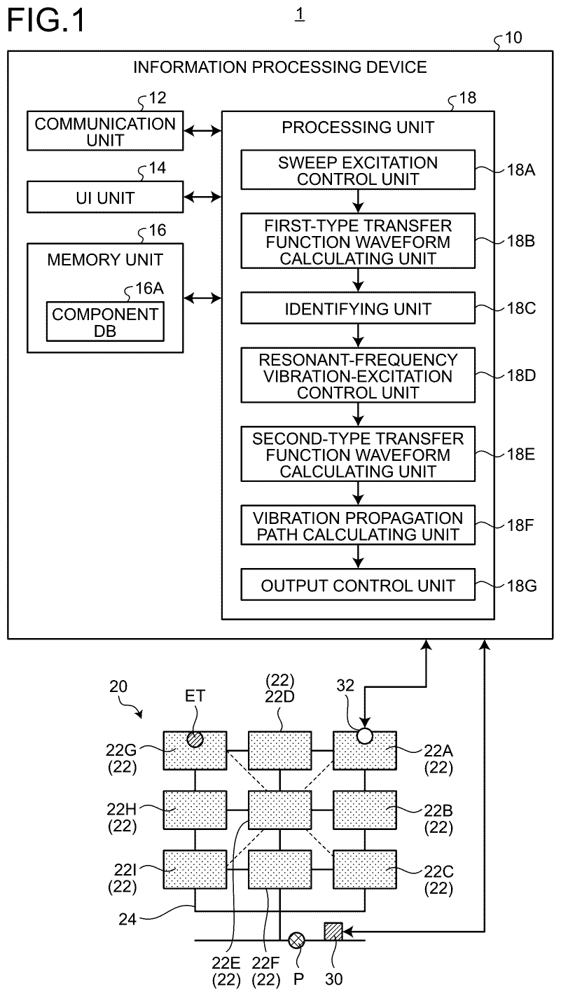

FIG. 1 is a schematic diagram illustrating an example of an information processing system 1 according to the present embodiment.

The information processing system 1 includes an information processing device 10, a vibration exciter 30, and an acceleration meter 32.

The information processing device 10 performs information processing such as calculation of the vibration propagation path arisen in a structure 20.

The structure 20 represents the measurement object to be subjected to the calculation of the vibration propagation path by the information processing device 10. The structure 20 is made of two or more components 22. The structure 20 is a device or a structural body that includes two or more components 22, some of which being physically coupled to each other either directly or via a supporting member 24.

Examples of the structure 20 include, but are not limited to, an electron beam exposure system for printing the circuit patterns of large-scale integration (LSI) using laser radiation, an exposure device that exposes and transfers images of mask patterns onto a photosensitive substrate, and a vehicle.

In a case where the structure 20 is an exposure device, the components 22 thereof include a laser radiation mechanism, a lens tube for holding optical members such as lenses, a table for holding a mask or a photosensitive substrate, a stage device for moving the table, and a housing. In a case where the structure 20 is a vehicle, the components 22 thereof include a chassis, undercarriage components, drive-train components, and panel components. Examples of an attachment method for attaching the components 22 to the structure 20 include an attachment method in which fastening is done using screws, nuts and bolts, and rivets, and an attachment method that involves welding, bonding, and fitting.

With reference to FIG. 1, the description is given about an example in which the structure 20 includes components 22A to 22I. Among the components 22A to 22I, at least some of them are physically coupled to each other either directly or via the supporting member 24. Therefore, the components 22A to 22I are coupled in a manner capable of vibrating and propagating via the supporting member 24 or via the other components 22.

Moreover, the structure 20 is provided with the vibration exciter 30 and the acceleration meter 32.

The vibration exciter 30 is a device for causing vibration excitation in the structure 20. The vibration exciter 30 and the information processing device 10 are connected to each other in a communicable manner. The vibration exciter 30 applies, to the structure 20, input vibrations that have the frequency and the amplitude in accordance with the control performed by the information processing device 10. In FIG. 1 is illustrated an example in which the vibration exciter 30 causes vibration excitation at a vibration excitation position P that is kept in contact with some region of the structure 20, and applies input vibrations to the structure 20. Alternatively, a speaker can be used as the vibration exciter 30, and input vibrations can be applied to the structure in a contactless manner using sound waves. In the present embodiment, the description is given about an example in which the vibration exciter 30 applies input vibrations to the structure 20 by causing vibration excitation at the vibration excitation position P.

The acceleration meter 32 represents an example of a vibration detector. The acceleration meter 32 is a device for measuring the vibrational acceleration occurring in the structure 20. The acceleration meter 32 and the information processing device 10 are connected to each other in a communicable manner. The acceleration meter 32 is disposed to be in contact with at least part of the components 22 of the structure 20, detects the vibrational acceleration occurring in those components 22, and sequentially sends the vibrational acceleration to the information processing device 10. In FIG. 1 is illustrated an example in which the acceleration meter 32 is disposed to be in contact with the component 22A from among the components 22 of the structure 20.

Note that, the installation position of the acceleration meter 32 can be changed by a user operation or the like. Thus, in accordance with a user operation, the acceleration meter 32 can be installed at the user-desired component 22 from among the components 22 of the structure 20.

Given below is the description about the information processing device 10.

The information processing device 10 includes a communication unit 12, a user interface (UI) unit 14, a memory unit 16, and a processing unit 18. Each of the communication unit 12, the UI unit 14, and the memory unit 16 is connected to the processing unit 18 in a communicable manner by a bus.

The communication unit 12 communicates with external information processing devices via a network. The UI unit 14 has an input function for receiving an operation input from the user, and has an output function for outputting a variety of information. The input function is represented by, for example, an input device such as a keyboard. The output function is represented by, for example, a display for displaying a variety of information or a speaker for outputting sounds. The memory unit 16 is used for storing a variety of information.

In the present embodiment, the memory unit 16 is used for storing a component database (DB) 16A.

In the component DB 16A, component information is registered as the information related to each of the components 22 of the structure 20. Each set of component information contains data, such as the material and the shape (dimensions of each part) of the corresponding component 22, which is required for logically calculating the resonant frequency (natural vibration frequency) of that component 22. When the components 22 of the structure 20 are designed using a design support system such as a CAD system (CAD stands for Computer Aided Design), the design data (CAD data) can be used as the component information.

The processing unit 18 is an arithmetic unit that performs information processing. The processing unit 18 includes a sweep excitation control unit 18A, a first-type transfer function waveform calculating unit 18B, an identifying unit 18C, a resonant-frequency vibration-excitation control unit 18D, a second-type transfer function waveform calculating unit 18E, a vibration propagation path calculating unit 18F, and an output control unit 18G. At least one of the sweep excitation control unit 18A, the first-type transfer function waveform calculating unit 18B, the identifying unit 18C, the resonant-frequency vibration-excitation control unit 18D, the second-type transfer function waveform calculating unit 18E, the vibration propagation path calculating unit 18F, and the output control unit 18G is implemented using one or more processors. The abovementioned constituent units can be implemented by causing a processor such as a CPU to execute a computer program, namely, can be implemented by using software. Alternatively, the abovementioned constituent units can be implemented using a processor such as a dedicated integrated circuit (IC), namely, can be implemented by using hardware. Still alternatively, the abovementioned constituent units can be implemented using a combination of software and hardware. In the case of using multiple processors, each processor can be used for implementing one of the constituent elements or can be used for implementing two or more constituent elements.

Note that, at least either at least one of the function units included in the processing unit 18 or at least part of a variety of information stored in the memory unit 16 can be provided in an external information processing device that is connected to the information processing device 10 in a communicable manner.

Moreover, the processing unit 18 can alternatively be implemented, for example, using one or more processing circuits from among a CPU, a microprocessor, a graphic processing unit (GPU), an application specific integrated circuit (ASIC), and a field-programmable gate array (ASIC), or can be implemented using an electronic circuit that includes such circuits. Still alternatively, the processing unit 18 can be implemented either using an information processing device such as a computer, or using a computer system in which computers or servers communicate with each other via a network, or using a PC cluster in which computers performs information processing in cooperation.

The sweep excitation control unit 18A controls the vibration exciter 30 to cause sweep excitation of the structure 20.

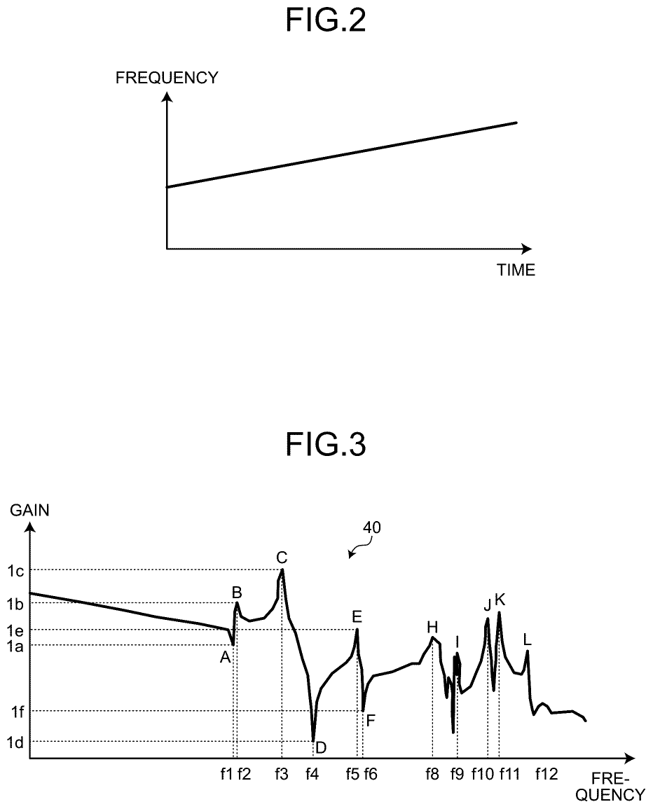

FIG. 2 is an explanatory diagram illustrating an example of sweep excitation. In FIG. 2, the horizontal axis represents the time, and the vertical axis represents the frequency.

Herein, sweep excitation means applying input vibrations to the structure 20 while varying the frequency. More specifically, sweep excitation means applying input vibrations to the structure 20 while continuously varying the frequency of the vibrations within a predetermined frequency range. The speed of continuously varying the frequency within the predetermined frequency range (i.e., the frequency sweep speed) can be set to include 5 to 10 cycles or more of signals with each frequency that varies.

In one example, sweep excitation means applying, to the structure 20, input vibrations whose frequency is continuously increased over time. Note that, in sweep excitation, as long as input vibrations having the frequency continuously varied over time are applied, it serves the purpose. Thus, input vibrations having the frequency continuously reduced over time can also be applied to the structure 20.

Returning to the description with reference to FIG. 1, the sweep excitation control unit 18A controls the vibration exciter 30 to apply, to the structure 20, input vibrations by way of sweep excitation. In one example, the sweep excitation control unit 18A outputs, to the vibration exciter 30, frequency information indicating the frequency that either gradually increase over time or gradually decrease over time, and amplitude information indicating the amplitude. As long as the amplitude information indicates an amplitude that does not cause breakage or slackness in the components 22 of the structure 20 and make it difficult to maintain the functionality of the structure 20, it serves the purpose. The vibration exciter 30 applies, to the structure 20 via the vibration excitation position P, input vibrations that have the amplitude indicated by the amplitude information received by the sweep excitation control unit 18A and that have the frequency indicated by the frequency information received by the sweep excitation control unit 18A.

Specifically, the sweep excitation control unit 18A controls the vibration exciter 30 to cause vibration excitation of the structure 20 while gradually varying the frequency of the vibrations either from a lower frequency band to a higher frequency band or from a higher frequency band to a lower frequency band during sweeping among the frequency bands within a predetermined range. The predetermined range of frequency bands is set to include the lowest resonant frequency and the highest resonant frequency from among the resonant frequencies of the components 22 of the structure 20.

With the control performed by the sweep excitation control unit 18A, the vibration exciter 30 applies, to the structure 20, input vibrations whose frequency is gradually varied over time.

The first-type transfer function waveform calculating unit 18B calculates a first-type transfer function waveform.

The first-type transfer function waveform indicates the relationship between the amplitude and the frequency of the output vibrations occurring in the components 22 of the structure 20 when sweep excitation is performed. The first-type transfer function waveform represents a frequency response function of the output vibrations occurring in the components 22 of the structure 20 when sweep excitation is performed. Herein, the amplitude is expressed by the gain (dB).

The first-type transfer function waveform calculating unit 18B divides, into plural time segments, time-series data of timing-by-timing vibrational accelerations, which are sequentially detected over time by the acceleration meter 32 during sweep excitation of the structure 20. Then, the first-type transfer function waveform calculating unit 18B calculates the first-type transfer function waveform by performing Fourier transformation with respect to the time-series data of the timing-by-timing vibrational accelerations.

FIG. 3 is a schematic diagram illustrating an example of a first-type transfer function waveform 40.

The first-type transfer function waveform 40 includes a plurality of first-type peaks. Thus, the first-type peaks represent peaks included in the first-type transfer function waveform 40.

In FIG. 3, first-type peaks A to F and H to L appear at frequency f1 to f6 and f8 to f12, respectively.

By performing sweep excitation, actual-measurement resonant frequency information about the components 22 of the structure 20 is obtained. The frequency at each first-type peak included in the first-type transfer function waveform 40 is equivalent to the actual measurement value of the resonant frequency of any of the components 22 of the structure 20. For that reason, in the example illustrated in FIG. 3, each of the frequencies f1 to f6 and f8 to f12 of the first-type peaks matches with the resonant frequency of any of the components 22 of the structure 20.

The following description is given by referring again to FIG. 1.

The identifying unit 18C identifies the frequency at each first-type peak in the first-type transfer function waveform 40 as the resonant frequency of any of the components 22 of the structure 20. In the example illustrated in FIG. 3, the identifying unit 18C identifies each of the frequencies f1 to f6 and f8 to f12 as the resonant frequency of any of the components 22 of the structure 20.

Moreover, the identifying unit 18C determines which of the components 22 whose resonant frequency is equal to frequency of the first-type peak included in the first-type transfer function waveform 40.

The identifying unit 18C calculates the theoretical resonant frequency of each component 22 by using component information about those components 22 registered in the component DB 16A. The calculation of theoretical resonant frequencies from the sets of component information can be performed using a known method.

Then, for each first-type peak included in the first-type transfer function waveform 40, the identifying unit 18C identifies the component 22 that has the theoretical resonant frequency matching with the frequency of that first-type peak (i.e., the actual-measurement resonant frequency), and thereby determines which of the components 22 whose resonant frequency is equal to frequency of the first-type peak included in the first-type transfer function waveform 40.

Note that one component 22 may have different theoretical resonant frequencies. In such a case, the identifying unit 18C identifies one or more resonant frequencies for each of the components 22 of the structure 20.

The resonant-frequency vibration-excitation control unit 18D controls the vibration exciter 30 to apply, to the structure 20, input vibrations having the resonant frequency that is identified by the identifying unit 18C, for a predetermined vibration excitation duration.

The resonant-frequency vibration-excitation control unit 18D selects, as resonant frequency to be tested, one of resonant frequencies that are identified by the identifying unit 18C.

The resonant-frequency vibration-excitation control unit 18D displays, on the UI unit 14, a list of resonant frequencies identified by the identifying unit 18C, and selects, as resonant frequency to be tested, one resonant frequency selected by the user with an operation instruction from the UI unit 14. Alternatively, the resonant-frequency vibration-excitation control unit 18D can select optional one resonant frequency, from among the resonant frequencies identified by the identifying unit 18C, as the resonant frequency to be tested.

Then, every time one resonant frequency is selected for testing, the resonant-frequency vibration-excitation control unit 18D controls the vibration exciter 30 to apply input vibrations having the selected resonant frequency to the structure 20 at a predetermined amplitude and for a predetermined vibration excitation duration.

More specifically, the resonant-frequency vibration-excitation control unit 18D outputs, to the vibration exciter 30, resonant frequency information indicating the selected resonant frequency, amplitude information indicating the amplitude, and vibration excitation duration information indicating the vibration excitation duration.

It is preferable that the amplitude information to be output to the vibration exciter 30 along with the resonant frequency information represents amplitude lower than the level of amplitude that affects the function of the components 22 of the structure 20. More specifically, it is preferable that the amplitude information indicates such an amplitude which is lower than the amplitude at which breakage or slackness starts to occur in the structure 20 and in the components 22 thereof and makes it difficult to maintain the functionality of the structure 20, and indicates such an amplitude which is weak enough to enable obtaining a transfer function waveform having plural peaks attributed to the input variations of the resonant frequency.

Regarding the vibration excitation duration information that is output to the vibration exciter 30 along with the resonant frequency, the detailed description will be given later.

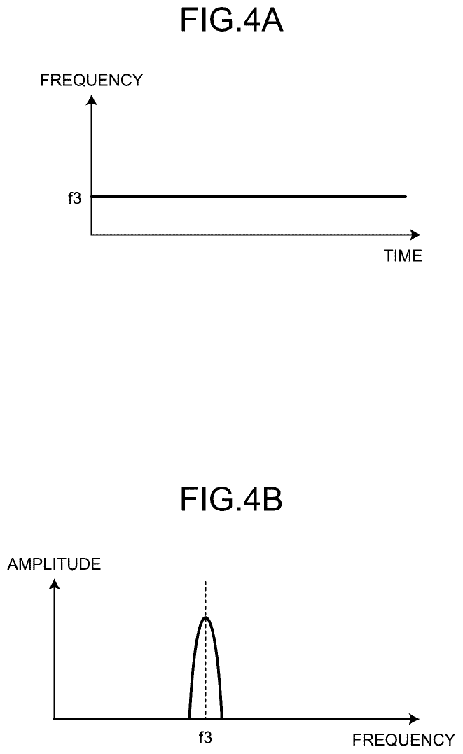

FIGS. 4A and 4B are diagrams illustrating an example of vibration excitation attributed to the input vibrations having a resonant frequency. In FIG. 4A, the horizontal axis represents time, and the vertical axis represents frequency. In FIG. 4B, the horizontal axis represents frequency, and the vertical axis represents amplitude.

As illustrated in FIG. 4A, during vibration excitation attributed to the input vibrations with resonant frequency, the structure is subjected to vibration excitation by the input vibrations having a constant resonant frequency that does not change over time. As illustrated in FIG. 4B, as long as the amplitude of the input vibrations having a resonant frequency satisfies the conditions described earlier, it serves the purpose.

The following description is given by referring again to FIG. 1.

The vibration exciter 30 continuously applies, to the structure 20, the input vibrations that have the resonant frequency indicated by the resonant frequency information received from the resonant-frequency vibration-excitation control unit 18D and that have the amplitude indicated by the received amplitude information. The input vibrations are applied for the vibration excitation duration indicated by the vibration excitation duration information received from the resonant-frequency vibration-excitation control unit 18D.

As described above, under the control of the resonant-frequency vibration-excitation control unit 18D, the vibration exciter 30 applies the input vibrations having the selected resonant frequency and having a predetermined amplitude. The input vibrations are continuously applied to the vibration excitation position P in the structure 20 for the vibration excitation duration.

When the input vibrations having the selected resonant frequency are applied to the structure 20, the component 22 of the structure 20, which has the selected resonant frequency, vibrates. Since the input vibrations with the selected resonant frequency are continuously applied for the vibration excitation duration, another component 22 resonates and then begins to vibrate at frequency different from the selected resonant frequency. Such resonance occurs in a larger number of components 22 in proportion to the duration of time for applying the input vibrations. Then, upon exceeding a given duration, the number of resonating components 22 becomes saturated. The start timing of the saturation in the number of components 22 starting to resonate is different depending on amplitude of the input vibrations having the concerned resonant frequency.

For that reason, for each of patterns having different combinations of the resonant frequency and the amplitude of the input vibrations, the processing unit 18 measures in advance, or identifies by a prediction operation, the start timing of the saturation in the number of components 22 starting to resonate over time since the vibration excitation caused by input vibrations. Then, as the common vibration excitation duration for all patterns, the processing unit 18 can calculate, in advance, the period of time starting from either the earliest timing from among the identified timings, or the latest timing, or the average timing to the start timing of vibration excitation attributed to the input vibrations. Alternatively, for each of patterns having different combinations of the resonant frequency and the amplitude of the input vibrations, the processing unit 18 can calculate in advance, as the vibration excitation duration, the period of time starting from the start timing of the saturation in the number of components 22 starting to resonate over time since the vibration excitation caused by input vibrations to the start timing of vibration excitation attributed to the input vibrations.

By performing such operations, the processing unit 18 calculates in advance the vibration excitation duration satisfying the above-described conditions for each combination of the type of the resonant frequency and the amplitude of the input vibrations. Then, the resonant-frequency vibration-excitation control unit 18D can identify the vibration excitation duration corresponding to the resonant frequency and the amplitude that are applied to the structure 20 as the vibration excitation duration of the input vibrations having the concerned resonant frequency and the concerned amplitude, and can perform the operations described above.

The following description is given by referring again to FIG. 1.

The second-type transfer function waveform calculating unit 18E calculates a second-type transfer function waveform.

The second-type transfer function waveform represents a waveform that, when the input vibrations having a resonant frequency are applied to the structure 20 for a predetermined vibration excitation duration, represents the relationship between the amplitude and the frequency of the output vibrations occurring in at least part of the components 22 of the structure 20. The second-type transfer function waveform represents a frequency response function of the output vibrations occurring in the components 22 of the structure 20 when the input vibrations having a resonant frequency are applied for the vibration excitation duration. Herein, the amplitude is expressed using the gain (dB).

The second-type transfer function waveform calculating unit 18E calculates the second-type transfer function waveform by dividing time-series data of timing-by-timing vibrational accelerations, which are sequentially detected over time by the acceleration meter 32 during vibration excitation of the structure 20 for the vibration excitation duration due to the input vibrations having a resonant frequency, into time segments, and performing Fourier transformation with respect to the time-series data of the timing-by-timing vibrational accelerations.

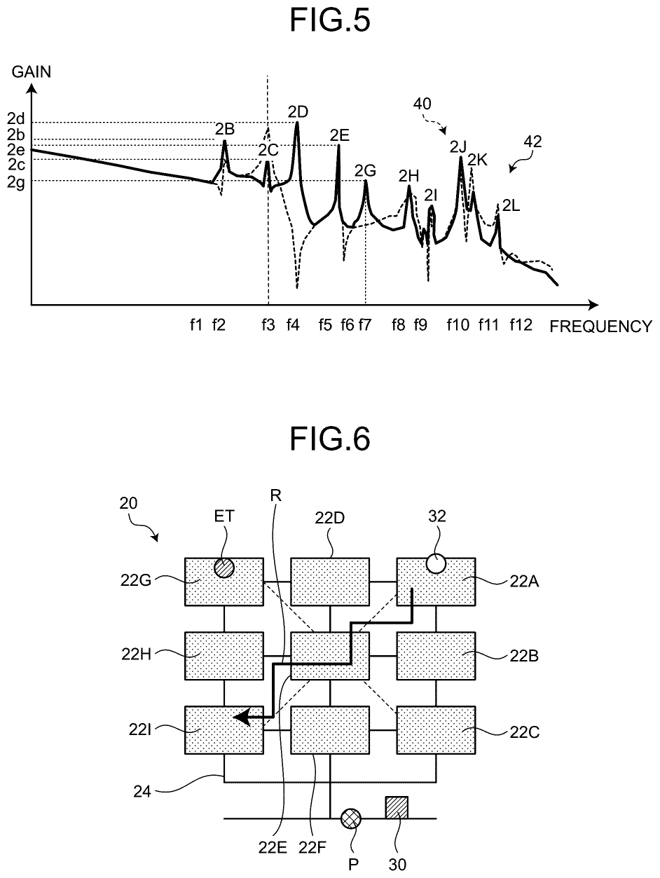

FIG. 5 is a schematic diagram illustrating an example of a second-type transfer function waveform 42.

The second-type transfer function waveform 42 includes second-type peaks. Thus, the second-type peaks represent peaks included in the second-type transfer function waveform 42.

In FIG. 5 is illustrated the second-type transfer function waveform 42 that is calculated based on the vibrational acceleration detected by the acceleration meter 32 when the input vibrations having the frequency f3, which is any of the resonant frequencies identified by the identifying unit 18C, are applied to the structure 20 for the vibration excitation duration. In FIG. 5, the first-type transfer function waveform 40 obtained by sweep excitation is also illustrated. In FIG. 5, the second-type transfer function waveform 42 is illustrated with a solid line, and the first-type transfer function waveform 40 is illustrated with a dotted line.

As illustrated in FIG. 5, when the input vibrations having the selected resonant frequency are applied to the structure 20, that component 22 of the structure 20 which has the concerned resonant frequency vibrates. Moreover, when the input vibrations having the selected resonant frequency are applied in a continuous manner for the vibration excitation duration, the vibrations of the component 22 having the selected resonant frequency cause resonance of the other components 22, and the other components 22 start vibrating at different frequencies than the selected resonant frequency. The number of components that start resonating becomes saturated due to the continuous vibration excitation attributed to the input vibrations for the vibration excitation duration. In other words, as long as the vibration excitation duration is equal to or larger than the period of time taken by the number of second-type peaks, which appear in the second-type transfer function waveform 42 measured when the input vibrations having a resonant frequency are applied to the structure 20, increases and starts to saturate due to the elapse of the vibration excitation period of the input vibrations, it serves the purpose.

In the example illustrated in FIG. 5, by applying the input vibrations having the resonant frequency f3 to the structure 20 for the vibration excitation duration, second-type peaks 2B to 2E and 2G to 2L occur at the frequencies f2 to f5 and f7 to f12, respectively.

Note that, when the input vibrations having a resonant frequency are applied to the structure 20, peaks that did not appear during sweep excitation may appear. On the contrary, there may be a case where peaks that did appear during sweep excitation do not appear when the input vibrations having a resonant frequency are applied.

Specifically, for instance, no first-type peak appears at the frequency f7 in the first-type transfer function waveform 40 illustrated in FIG. 3, whereas the second-type peak 2G appears at the frequency f7 in the second-type transfer function waveform 42 illustrated in FIG. 5. Moreover, the first-type peaks A and F appear at the frequencies f1 and f6, respectively, in the first-type transfer function waveform 40 illustrated in FIG. 3, whereas there are no second-type peaks appearing at the frequencies f1 and f6 in the second-type transfer function waveform 42 illustrated in FIG. 5.

In this way, when the input vibrations having a particular frequency are continuously applied to the structure 20 for the vibration excitation duration, different peaks appear than the peaks appearing when the input vibrations are applied for a short period of time. For that reason, by analyzing the second-type transfer function waveform 42, peaks that were not detected during short-term vibration excitation can be detected.

The following description is given by referring again to FIG. 1.

The vibration propagation path calculating unit 18F calculates a vibration propagation path, along which the input vibrations having a resonant frequency propagate in the structure 20 when the input vibrations are applied to the structure 20. The vibration propagation path is calculated based on the second-type peaks included in the second-type transfer function waveform 42 and based on the half widths of the second-type peaks. Thus, the vibration propagation path is a path of propagation of vibrations in the structure 20.

Specifically, the vibration propagation path calculating unit 18F calculates the vibration propagation path by using the second-type transfer function waveform 42 that is calculated in accordance with the vibrational acceleration detected by the acceleration meter 32 installed in a component 22.

The vibration propagation path calculating unit 18F identifies the half width of each of second-type peaks included in the second-type transfer function waveform 42. The identification of the half width can be performed by a known method for calculating the half width of a peak.

The vibration propagation path calculating unit 18F recognizes that, the smaller the half width of frequency of the second-type peak as resonant frequency of a component 22 is, the shorter a propagation distance of vibration from the acceleration meter 32 to the component 22 is. The acceleration meter 32 detected the vibrational acceleration used in the calculation of the second-type transfer function waveform 42. Subsequently, the vibration propagation path calculating unit 18F calculates, as the vibration propagation path, a propagation path obtained by concatenating a component 22 whose resonant frequency is equal to frequency of a second-type peak having smaller half width and another component 22 whose resonant frequency is equal to frequency of a second-type peak having larger half width.

The following description is given with reference to FIG. 5. It is assumed that the waveform illustrated with a solid line in FIG. 5 represents the second-type transfer function waveform 42 that is calculated in accordance with the vibrational acceleration measured when the input vibrations having the resonant frequency f3 are applied to the structure 20 for a predetermined vibration excitation duration.

In that case, the vibration propagation path calculating unit 18F identifies the half width of each of the second-type peaks 2B to 2E and 2G to 2L. Moreover, the vibration propagation path calculating unit 18F identifies, by using the component DB 16A, the components 22 whose resonant frequencies are equal to frequency of the second-type peaks 2B to 2E and 2G to 2L.

The vibration propagation path calculating unit 18F sorts, in an ascending order of the half width of the second-type peaks, pieces of component information about the components 22 having the resonant frequency equal to frequency at the second-type peaks. Then, the vibration propagation path calculating unit 18F recognizes that, the smaller (or narrower) the half width of frequency of the second-type peak as resonant frequency of a component 22 is, the shorter a propagation distance of vibration from the acceleration meter 32 to the component 22 is. The propagation distance of the vibrations represents the distance required for propagation of the vibrations. The propagation distance of the vibrations does not mean the physical shortest distance but instead means the distance along the propagation path of the vibrations. Then, the vibration propagation path calculating unit 18F calculates, as the vibration propagation path in which the component 22 having the resonant frequency represents the excitation source, a propagation path obtained by sequentially concatenating, in an ascending order of the half width, the components 22 identified by the sets of component information arranged in an ascending order of the half width.

Moreover, the vibration propagation path calculating unit 18F recognizes, as the excitation source, a component 22 in the vibration propagation path that has the resonant frequency used for the input vibrations and calculates, as the vibration propagation direction in the vibration propagation path, the direction moving away from the component 22, which represents the excitation source, along the vibration propagation path.

FIG. 6 is an explanatory diagram illustrating an example of a vibration propagation path R.

It is assumed that the acceleration meter 32 is installed in the component 22A, and, when the input vibrations having the frequency equal to the resonant frequency of the component 22A are applied to the structure 20 in a continuous manner for the vibration excitation duration using the vibration exciter 30, the second-type transfer function waveform 42 is obtained that is calculated in accordance with the vibrational acceleration detected by the acceleration meter 32. Then, it is assumed that by the analysis of the second-type transfer function waveform 42 performed by the vibration propagation path calculating unit 18F, among the second-type peaks included in the second-type transfer function waveform 42, a second-type peak corresponding to the resonant frequency of the component 22A has the narrowest half width and the second-type peaks corresponding to the resonant frequencies of the components 22E and 22I in that order have expanded half widths.

In that case, when the input vibrations having the frequency equal to the resonant frequency of the component 22A are applied to the structure 20 for the vibration excitation duration, the vibration propagation path calculating unit 18F calculates the path from the component 22A toward the component 22I via the component 22E as the vibration propagation path R. Moreover, in that case, the vibration propagation path R treats the component 22A, which has the resonant frequency used for the input vibrations, as the excitation source, and calculates the direction moving away from the component 22A along the vibration propagation path R as the vibration propagation direction (refer to the direction of array of the vibration propagation path R illustrated in FIG. 2).

As described earlier, the installation position of the acceleration meter 32 can be changed by a user operation or the like. For that reason, from the perspective of calculating the vibration propagation path R in a more accurate manner, it is preferable that the acceleration meter 32 is either installed in the component 22 that has the resonant frequency equal to the frequency of the input vibrations applied to the vibration exciter 30 by the resonant-frequency vibration-excitation control unit 18D or installed in another component 22 that is adjacent to or in contact with the abovementioned component 22.

Before the resonant-frequency vibration-excitation control unit 18D causes vibration excitation using the input vibrations having a resonant frequency, the processing unit 18 may display, on the UI unit 14, the resonant frequency selected as the measurement target and the identification information about the component 22 having that resonant frequency. After confirming the identification information about the component 22 displayed on the UI unit 14, the user installs the acceleration meter 32 in the component 22 identified by that identification information and then operates the UI unit 14 to input a measurement start instruction signal. Upon receiving the measurement start instruction signal, the resonant-frequency vibration-excitation control unit 18D can control the vibration exciter 30 to apply the input vibrations, which have the selected resonant frequency, for a predetermined vibration excitation duration.

Note that, for the one resonant frequency selected as the testing target by the resonant-frequency vibration-excitation control unit 18D, the resonant-frequency vibration-excitation control unit 18D, the second-type transfer function waveform calculating unit 18E, and the vibration propagation path calculating unit 18F may sequentially vary the installation position of the acceleration meter 32 in the structure 20, and, every time the installation position of the acceleration meter 32 is varied, may perform the operations described earlier and calculate the second-type transfer function waveform 42.

In that case, with respect to the single resonant frequency selected as the testing target, the vibration propagation path calculating unit 18F obtains multiple types of second-type transfer function waveforms 42 calculated based on the detection results of the vibrational acceleration measured by the acceleration meter 32 installed at different positions. Then, the vibration propagation path calculating unit 18F can calculate the vibration propagation path R on the basis of the multiple types of second-type transfer function waveforms 42 calculated in accordance with the vibrational acceleration detected by the acceleration meters 32 installed in mutually different components 22.

In an identical manner to the description given earlier, regarding the acceleration meter 32 installed at each different position, the vibration propagation path calculating unit 18F uses the half widths of the second-type peaks identified from the second-type transfer function waveform 42 and calculates, as the vibration propagation path in which the component 22 having the concerned resonant frequency represents the excitation source, the propagation path obtained by sequentially concatenating, in an ascending order of the half widths, the components 22 identified by the sets of component information arranged in an ascending order of the half widths. Moreover, the vibration propagation path calculating unit 18F treats, as the excitation source, that component 22 in the vibration propagation path which has the resonant frequency used for the input vibrations, and defines the direction moving away from that component 22 along the vibration propagation path as the vibration propagation direction in the vibration propagation path.

Then, with respect to the single resonant frequency selected as the testing target, the vibration propagation path calculating unit 18F can calculate, as the vibration propagation path R with respect to that resonant frequency, the vibration propagation path that, from among the vibration propagation paths calculated for the acceleration meter 32 installed at different positions, has the highest number of overlapping paths with other vibration propagation paths.

More specifically, with respect to the single resonant frequency selected as the testing target, the vibration propagation path calculating unit 18F identifies, regarding multiple types of vibration propagation paths calculated for the acceleration meter 32 installed at different positions, the components 22 that are calculated for the highest number of times at each ranking in an ascending order of the distance along the respective vibration propagation paths from the component 22 representing the excitation source. Then, the vibration propagation path calculating unit 18F can calculate, as the vibration propagation path R with respect to the resonant frequency, the propagation path obtained by sequentially concatenating the components 22 that are identified at each ranking in an ascending order of the distance from the component 22 representing the excitation source.

Therefore, for each resonant frequency selected as the testing target, the vibration propagation path calculating unit 18F can calculate the vibration propagation path R on the basis of multiple second-type transfer function waveforms 42 corresponding to different installation positions of the acceleration meter 32, and hence can calculate the vibration propagation path R in a more accurate manner.

Note that the structure 20 may be configured such that two or more of the components 22 are each provided with the acceleration meter 32. In one example, the structure 20 is configured such that all the components 22 of the structure 20 are each provided with the acceleration meter 32.

In that case, with respect to the single resonant frequency selected as the testing target, the vibration propagation path calculating unit 18F obtains, in parallel, second-type transfer function waveforms 42 on the basis of the detection result of the vibrational acceleration detected substantially at the same time by the acceleration meters 32 installed at different positions. In that case, the time required by the user to vary the installation positions of the acceleration meter 32 can be reduced, and the vibration propagation path R can be calculated in a shorter period of time, at a fast rate, and in a more accurate manner.

Note that, for each selected resonant frequency and for each installation condition of the acceleration meter 32 of a single type, the vibration propagation path calculating unit 18F can perform control to apply, to the structure 20 for the vibration excitation duration, the input vibrations having each of multiple types of amplitudes obtained by varying the amplitude.

In that case, the amplitudes can be mutually different within a range smaller than the amplitude that affects the functions of the components 22 of the structure 20.

Then, regarding the single resonant frequency selected as the testing target by the resonant-frequency vibration-excitation control unit 18D, the resonant-frequency vibration-excitation control unit 18D, the second-type transfer function waveform calculating unit 18E, and the vibration propagation path calculating unit 18F can sequentially vary the amplitude of the input vibrations within a range satisfying the conditions described earlier and, every time the amplitude is varied, can calculate the second-type transfer function waveform 42 by performing the operations identical to the operation described earlier.

In that case, with respect to the single resonant frequency selected as the testing target, the vibration propagation path calculating unit 18F can obtain multiple types of second-type transfer function waveforms 42 corresponding to different amplitudes of the input vibrations.

Then, in an identical manner to the description given earlier, for each different amplitude, the vibration propagation path calculating unit 18F uses the half widths of the second-type peaks identified from the second-type transfer function waveforms 42 and calculates, as the vibration propagation path in which the component 22 having the concerned resonant frequency represents the excitation source, the propagation path obtained by sequentially concatenating, in an ascending order of the half widths, the components 22 identified by the sets of component information arranged in an ascending order of the half widths. Moreover, the vibration propagation path calculating unit 18F treats, as the excitation source, that component 22 in the vibration propagation path which has the resonant frequency used for the input vibrations and calculates, as the vibration propagation direction in the vibration propagation path, the direction moving away from the component 22, which represents the excitation source, along the vibration propagation path.

Then, with respect to the single resonant frequency selected as the testing target, the vibration propagation path calculating unit 18F can calculate, as the vibration propagation path R with respect to that resonant frequency, the vibration propagation path that, from among the vibration propagation paths calculated for different amplitudes, has the highest number of overlapping paths with other vibration propagation paths.

More specifically, with respect to the single resonant frequency selected as the testing target, the vibration propagation path calculating unit 18F identifies, regarding multiple types of vibration propagation paths calculated for different amplitudes, the components 22 that are calculated for the highest number of times at each ranking in an ascending order of the distance along the respective vibration propagation paths from the component 22 representing the excitation source. Then, the vibration propagation path calculating unit 18F can calculate, as the vibration propagation path R with respect to the resonant frequency, the propagation path obtained by sequentially concatenating the components 22 that are identified at each ranking in an ascending order of the distance from the component 22 representing the excitation source.

Moreover, with respect to the single resonant frequency selected as the testing target, in an identical manner to the description given earlier, the processing unit 18 can calculate plural vibration propagation paths having different combinations of the installation position of the acceleration meter 32 and the amplitude and, using the calculated vibration propagation paths, can calculate the vibration propagation path R with respect to the selected resonant frequency in an identical manner to the description given above.

Herein, the resonant-frequency vibration-excitation control unit 18D, the second-type transfer function waveform calculating unit 18E, the vibration propagation path calculating unit 18F can sequentially select one of resonant frequencies identified by the identifying unit 18C, and can perform the operations described above.

In that case, for the resonant frequency of each of the components 22 identified during sweep excitation, the resonant-frequency vibration-excitation control unit 18D, the second-type transfer function waveform calculating unit 18E, and the vibration propagation path calculating unit 18F become able to calculate the vibration propagation path R in which the component 22 having the concerned resonant frequency represents the excitation source.

The output control unit 18G outputs the vibration propagation path R that is calculated by the vibration propagation path calculating unit 18F. More specifically, the output control unit 18G outputs the vibration propagation path R, which is calculated by the vibration propagation path calculating unit 18F, to at least either the UI unit 14, or the memory unit 16, or an external information processing device connected via the communication unit 12. Herein, the output control unit 18G can output the vibration propagation path R, which is calculated by the vibration propagation path calculating unit 18F, along with at least either the identification information about the component 22 representing the excitation source in the vibration propagation path R or the resonant frequency of the input vibrations that were used in calculating the vibration propagation path R.

Consider a case in which the output control unit 18G outputs the following information to the UI unit 14: the vibration propagation path R, the identification information about the component 22 representing the excitation source for the vibration propagation path R, and the resonant frequency of the input vibrations that were used in calculating the vibration propagation path R. In that case, by looking at the UI unit 14 and confirming the vibration propagation path R, the identification information about the component 22 representing the excitation source for the vibration propagation path R, and the resonant frequency of the input vibrations that were used in calculating the vibration propagation path R, the user becomes able to confirm the vibration propagation path R formed when the input vibrations having the concerned resonant frequency are applied to the structure 20. Moreover, the user becomes able to confirm that, at the time of formation of the vibration propagation path R, the component 22 identified by the identification information represents the excitation source.

Note that, as illustrated in FIG. 1, there may be a case where an evaluation target ET is disposed in the structure 20. In one example, the evaluation target ET represents that part of the structure 20 in which the vibrations are to be particularly suppressed. When the structure 20 is, for example, an electron beam exposure system, the evaluation target ET is a component 22 serving as a laser radiation device, a component 22 on which a laser radiation device is mounted, or the like.

In that case, the processing unit 18 can calculate the vibration propagation path R for each of the identified types of resonant frequencies, and hence becomes able to identify the resonant frequency, the component 22 having the resonant frequency, and the vibration propagation path R that are responsible for the vibrations occurring in the component 22 that is either installed in the evaluation target ET or itself represents the evaluation target ET.

In one example, the processing unit 18 identifies, from among the calculated vibration propagation paths R, a vibration propagation path R passing through the evaluation target ET or through the component 22 in which the evaluation target ET is installed (in FIG. 1, the component 22G). Then, to at least either the UI unit 14, or the memory unit 16, or an external information processing device, the processing unit 18 can output the following information as the information affecting the vibration of the evaluation target ET: the identified vibration propagation path R, the resonant frequency of the input vibrations used in calculating that vibration propagation path R, and the identification information about the component 22 representing the excitation source in that vibration propagation path R.

Therefore, by looking at the information output to the UI unit 14, the user becomes able to easily confirm the following: the resonant frequency that is likely to cause vibrations in the evaluation target ET, the vibration propagation path R formed when the input vibrations having the concerned resonant frequency are applied to the structure 20, and the component 22 representing the excitation source.

Given below is the description of an exemplary procedure of information processing performed by the processing unit 18 of the information processing device 10.

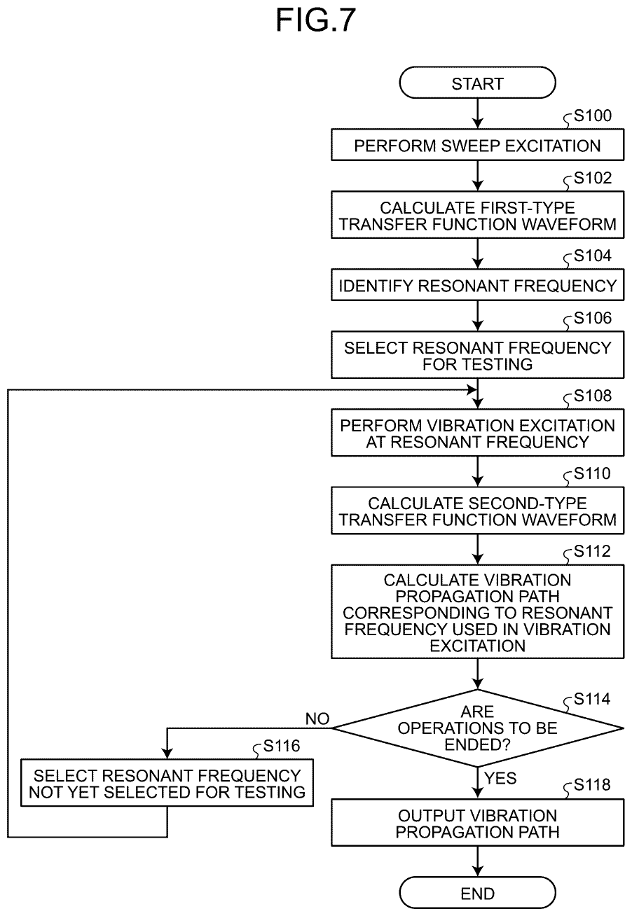

FIG. 7 is a flowchart for explaining an exemplary procedure of information processing performed by the processing unit 18.

The sweep excitation control unit 18A performs sweep excitation and controls the vibration exciter 30 to ensure that the structure 20 is subjected to sweep excitation (Step S100).

The first-type transfer function waveform calculating unit 18B calculates the first-type transfer function waveform 40 (Step S102). The first-type transfer function waveform calculating unit 18B divides, into plural time segments, time-series data of timing-by-timing vibrational accelerations, which are sequentially detected over time by the acceleration meter 32 during sweep excitation of the structure 20 performed at Step S100. Then, the first-type transfer function waveform calculating unit 18B calculates the first-type transfer function waveform 40 by performing Fourier transformation with respect to the time-series data of the timing-by-timing vibrational accelerations.

The identifying unit 18C identifies the frequency of each of the first-type peaks included in the first-type transfer function waveform 40, which is calculated at Step S102, as the resonant frequency of any of the components 22 of the structure 20 (Step S104). In the example illustrated in FIG. 3, the identifying unit 18C identifies each of the frequencies f1 to f6 and f8 to f12 as the resonant frequency of any of the components 22 of the structure 20. Moreover, the identifying unit 18C may also identify the correspondence between the frequencies of the first-type peaks included in the first-type transfer function waveform 40 and the resonant frequencies of the components 22 of the structure 20.

The resonant-frequency vibration-excitation control unit 18D selects, from among the resonant frequencies identified at Step S104, a single resonant frequency as the testing target (Step S106).

The resonant-frequency vibration-excitation control unit 18D controls the vibration exciter 30 to apply, to the structure 20, input vibrations, which have the resonant frequency selected as the testing target at Step S106 or Step S118 (described later), at a predetermined amplitude and for a predetermined vibration excitation duration (Step S108).

The second-type transfer function waveform calculating unit 18E calculates the second-type transfer function waveform 42 (Step S110). The second-type transfer function waveform calculating unit 18E divides, into time segments, time-series data of timing-by-timing vibrational accelerations, which are sequentially detected over time by the acceleration meter 32 during vibration excitation of the structure 20 for the vibration excitation duration due to the input vibrations that have the concerned resonant frequency and that are applied at Step S108. Then, the second-type transfer function waveform calculating unit 18E calculates the second-type transfer function waveform 42 by performing Fourier transformation with respect to the time-series data of the timing-by-timing vibrational accelerations.

Based on the frequencies and the half widths of the second-type peaks included in the second-type transfer function waveform 42 calculated at Step S110, the vibration propagation path calculating unit 18F calculates the vibration propagation path R along which the input vibrations having the concerned resonant frequency propagate in the structure 20 when the input vibrations are applied to the structure 20 (Step S112).

Note that, as described earlier, regarding the single resonant frequency selected as the testing target by the resonant-frequency vibration-excitation control unit 18D at Step S108 or Step S118, the resonant-frequency vibration-excitation control unit 18D, the second-type transfer function waveform calculating unit 18E, and the vibration propagation path calculating unit 18F can sequentially vary the installation position of the acceleration meter 32 in the structure 20 and, every time the installation position of the acceleration meter 32 is varied, can perform the operations described above and calculate the second-type transfer function waveform 42. Moreover, regarding the single resonant frequency selected as the testing target by the resonant-frequency vibration-excitation control unit 18D at Step S108 or Step S118, the resonant-frequency vibration-excitation control unit 18D, the second-type transfer function waveform calculating unit 18E, and the vibration propagation path calculating unit 18F can keep the installation position of the acceleration meter 32 fixed, can perform the operations using multiple types of input vibrations created by varying the amplitude, and can calculate the second-type transfer function waveforms 42.

In that case, with respect to the single resonant frequency selected as the testing target, the vibration propagation path calculating unit 18F obtains the second-type transfer function waveforms 42 including at least either the second-type transfer function waveforms 42 calculated based on the acceleration meter 32 installed at different positions or the second-type transfer function waveforms 42 having different amplitudes.

In that case, as described earlier, the vibration propagation path calculating unit 18F can calculate the vibration propagation path for each of the second-type transfer function waveforms 42, and can treat the vibration propagation path having the highest number of overlapping paths with other vibration propagation paths as the vibration propagation path R corresponding to the concerned resonant frequency.

Subsequently, the processing unit 18 determines whether or not to end the operation of calculating the vibration propagation path R (Step S114). In one example, the processing unit 18 performs the determination at Step S114 by determining whether or not an end signal indicating an end instruction is received, which is input by an operation instruction from the user using the UI unit 14. Alternatively, the processing unit 18 can perform the determination at Step S114 by determining whether or not the operations from Step S108 to Step S112 have been performed for all resonant frequencies identified at Step S104.

When the determination at Step S114 is not affirmative (No at Step S114), then the system control proceeds to Step S116. At Step S116, the resonant-frequency vibration-excitation control unit 18D selects, from among the resonant frequencies identified at Step S104, a resonant frequency that is not yet selected as the testing target (Step S116), and the system control proceeds to Step S118. Note that, at Step S116, the resonant-frequency vibration-excitation control unit 18D can select, from among the resonant frequencies identified at Step S104, one resonant frequency that is selected in response to an operation instruction issued by the user using the UI unit 14.

When the determination at Step S114 is affirmative (Yes at Step S114), the system control proceeds to Step S118. At Step S118, the output control unit 18G outputs the vibration propagation path R that was calculated at Step S112 (Step S118). Specifically, the output control unit 18G outputs the following information to the UI unit 14: the vibration propagation path R, the identification information about the component 22 representing the excitation source for the vibration propagation path R, and the resonant frequency of the input vibrations that were used in calculating the vibration propagation path R.

As described above, in the information processing device 10 according to the present embodiment, the processing unit 18 identifies, as the resonant frequencies of the components 22 of the structure 20, the frequencies of the first-type peaks included in the first-type transfer function waveform 40 that represents the relationship between amplitude and frequency of output vibrations. The output vibrations occur in the components 22 of the structure 20 when the structure 20 is subjected to sweep excitation. Then, the processing unit 18 calculates the vibration propagation path R along which the input vibrations having the resonant frequency propagates in the structure 20 when the input vibrations are applied to the structure 20. The vibration propagation path R is calculated based on the frequencies and the half widths of the second-type peaks included in the second-type transfer function waveform 42 representing the relationship between the amplitude and the frequency of the output vibrations. The output vibrations occur in at least part of the components 22 of the structure 20 when the input vibrations of a resonant frequency are applied to the structure 20 for a predetermined vibration excitation duration.

In this way, in the information processing device 10 according to the present embodiment, the processing unit 18 calculates the vibration propagation path R, along which the vibrations propagate in the structure 20, using the frequencies and the half widths of the second-type peaks included in the second-type transfer function waveform 42.

Therefore, the information processing device 10 according to the present becomes able to provide the vibration propagation path R.

Given below is the description of an exemplary hardware configuration of the information processing device 10 according to the embodiment described above.

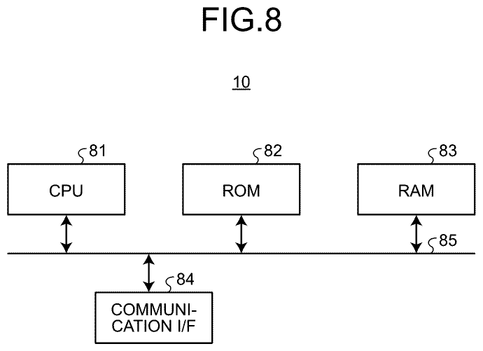

FIG. 8 is an exemplary hardware configuration diagram of the information processing device 10 according to the embodiment described above.

The information processing device 10 according to the embodiment described above has the hardware configuration of a normal computer in which a central processing unit (CPU) 81, a read only memory (ROM) 82, a random access memory (RAM) 83, and a communication I/F 84 are connected to each other by a bus 85.

The CPU 81 is an arithmetic device that controls the information processing device 10 according to the embodiment described above. The ROM 82 is used for storing a computer program that enables the CPU 81 to implement various operations. Herein, although the description is given with reference to a CPU, it is alternatively possible to use a graphics processing unit (GPU) as the arithmetic device that controls the information processing device 10. The RAM 83 is used for storing the data required by the CPU 81 in performing various operations. The communication I/F 84 is an interface for sending and receiving data.

In the information processing device 10 according to the embodiment described above, the CPU 81 reads the computer program from the ROM 82 into the RAM 83 and executes it, so that the functions described earlier are implemented in the computer.

Note that, the computer program used for executing the operations performed in the information processing device 10 according to the embodiment described above can alternatively be stored in a hard disk drive (HDD). Still alternatively, the computer program used for executing the operations performed in the information processing device 10 according to the embodiment described above can be stored in advance in the ROM 82.

Still alternatively, the computer program used for executing the operations performed in the information processing device 10 according to the embodiment described above can be stored as an installable file or an executable file in a computer-readable memory medium such as a compact disc read only memory (CD-ROM), a compact disc recordable (CD-R), a memory card, a digital versatile disk (DVD), or a flexible disk (FD), and can be provided as a computer program product. Still alternatively, the computer program used for executing the operations performed in the information processing device 10 according to the embodiment described above can be stored in a downloadable manner in a computer connected to a network such as the Internet. Still alternatively, the computer program used for executing the operations performed in the information processing device 10 to the information processing device 10E according to the embodiment described above can be distributed via a network such as the Internet.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The present disclosure includes the configurations described below.

(1) An information processing device comprising
a hardware processor connected to a memory and configured to:
   identify, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
   calculate a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.

(2) The information processing device according to the configuration (1), wherein the hardware processor is configured to perform the calculation of the vibration propagation path on the basis of the second-type transfer function waveform calculated in accordance with vibrational acceleration detected by a vibration detector installed in the part of the components.

(3) The information processing device according to the configuration (1) or (2), wherein the hardware processor is configured to
recognize that, the smaller the half width of frequency of the second-type peak as resonant frequency of a component is, the shorter a propagation distance of vibration from the vibration detector to the component is, and
calculate, as the vibration propagation path, a propagation path obtained by concatenating a component whose resonant frequency is equal to frequency of the second-type peak having smaller half width and another component whose resonant frequency is equal to frequency of the second-type peak having larger half width.

(4) The information processing device according to any one of the configurations (1) to (3), wherein the vibration excitation duration is equal to or larger than a period of time in which number of the second-type peaks included in the second-type transfer function waveform increases and starts to saturate due to elapse in vibration excitation period of input vibration, the second-type transfer function waveform being measured when input vibration having the resonant frequency is applied to the structure.

(5) The information processing device according to any one of the configurations (1) to (4), wherein the hardware processor is configured to perform the calculation of the vibration propagation path on the basis of multiple types of the second-type transfer function waveform detected by vibration detectors installed in the components different from each other.

(6) The information processing device according to any one of the configurations (1) to (5), wherein the hardware processor is configured to perform the calculation of the vibration propagation path on the basis of the second-type peaks included in the second-type transfer function waveform, the second-type transfer function waveform being obtained by applying, for the vibration excitation duration to the structure, input vibration having the resonant frequency with amplitude smaller than amplitude affecting function of the components of the structure.

(7) The information processing device according to any one of the configurations (1) to (6), wherein the hardware processor is configured to perform the calculation of the vibration propagation path on the basis of the second-type peaks included in each of multiple types of the second-type transfer function waveform, the multiple types of the second-type transfer function waveform being obtained by applying, for the vibration excitation duration to the structure, input vibrations having the resonant frequency with multiple types of amplitude each being smaller than the amplitude affecting function of the components.

(8) An information processing method implemented by a computer, the method comprising:
identifying, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
calculating a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.

(9) A computer program product comprising a non-transitory computer-readable recording medium on which a program executable by a computer is recorded, the program instructing the computer to:
identify, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
calculate a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.

What is claimed is:

1. An information processing device comprising
a hardware processor connected to a memory and configured to:
identify, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
calculate a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.

2. The information processing device according to claim 1, wherein the hardware processor is configured to perform the calculation of the vibration propagation path on the basis of the second-type transfer function waveform calculated in accordance with vibrational acceleration detected by a vibration detector installed in the part of the components.

3. The information processing device according to claim 2, wherein the hardware processor is configured to
recognize that, the smaller the half width of frequency of the second-type peak as resonant frequency of a component is, the shorter a propagation distance of vibration from the vibration detector to the component is, and
calculate, as the vibration propagation path, a propagation path obtained by concatenating a component whose resonant frequency is equal to frequency of the second-type peak having smaller half width and another component whose resonant frequency is equal to frequency of the second-type peak having larger half width.

4. The information processing device according to claim 1, wherein the vibration excitation duration is equal to or larger than a period of time in which number of the second-type peaks included in the second-type transfer function waveform increases and starts to saturate due to elapse in vibration excitation period of input vibration, the second-type transfer function waveform being measured when input vibration having the resonant frequency is applied to the structure.

5. The information processing device according to claim 1, wherein the hardware processor is configured to perform the calculation of the vibration propagation path on the basis of multiple types of the second-type transfer function waveform detected by vibration detectors installed in the components different from each other.

6. The information processing device according to claim 1, wherein the hardware processor is configured to perform the calculation of the vibration propagation path on the basis of the second-type peaks included in the second-type transfer function waveform, the second-type transfer function waveform being obtained by applying, for the vibration excitation duration to the structure, input vibration having the resonant frequency with amplitude smaller than amplitude affecting function of the components of the structure.

7. The information processing device according to claim 6, wherein the hardware processor is configured to perform the calculation of the vibration propagation path on the basis of the second-type peaks included in each of multiple types of the second-type transfer function waveform, the multiple types of the second-type transfer function waveform being obtained by applying, for the vibration excitation duration to the structure, input vibrations having the resonant frequency with multiple types of amplitude each being smaller than the amplitude affecting function of the components.

8. An information processing method implemented by a computer, the method comprising:
identifying, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
calculating a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.

9. A computer program product comprising a non-transitory computer-readable recording medium on which a program executable by a computer is recorded, the program instructing the computer to:
identify, as resonant frequency of components of a structure, frequency of first-type peaks included in a first-type transfer function waveform representing relationship between amplitude and frequency of output vibration, the output vibration occurring in the components of the structure when the structure is subjected to sweep excitation; and
calculate a vibration propagation path along which input vibration having the resonant frequency propagates when applied to the structure, the vibration propagation path being calculated based on frequency and half width of second-type peaks included in a second-type transfer function waveform representing relationship between amplitude and frequency of output vibration, the output vibration occurring in at least part of the components of the structure when the input vibration is applied to the structure for a predetermined vibration excitation duration.
